(19) United States
(12) Patent Application Publication
(10) Pub. No.: US 2006/0098415 A1
(43) Pub. Date: May 11, 2006

(54) Plasma display panel (PDP) supporting member and PDP including the supporting member

(76) Inventors: Ki-Jung Kim, Suwon-si (KR); Kyoung-Ho Kang, Suwon-si (KR)

Correspondence Address: Robert E. Bushnell, Suite 300, 1522 K Street, N.W., Washington, DC, 20005-1202, US

(21) Appl. No.: 11/261,664

(22) Filed: Oct. 31, 2005

(30) Foreign Application Priority Data
Nov. 10, 2004 (KR) 10-2004-0091526

(51) Int. Cl. H05K 1/14

(52) U.S. Cl. 361/740; 361/736; 248/917; 248/918

(57) ABSTRACT

A tension member to support a Plasma Display Panel (PDP) and a PDP including the tension member include: a rim portion extending to surround an edge of the PDP, the rim portion having a zigzag or serpentine shape; and portions included in the rim portion, the portions included in the rim portion including substrate insertion holes adapted to receive portions of edges of substrates included in the PDP. The portions included in the rim portion are adapted to isolate the PDP with respect to vibration. A heat conductive sheet is arranged between a back substrate of the PDP and a chassis base, the heat conductive sheet covering an entire area of the back substrate.

### CLAIM OF PRIORITY

This application makes reference to, incorporates the same herein, and claims all benefits accruing under 35 U.S.C. §119 from an application for SUPPORTING MEMBER OF PLASMA DISPLAY PANEL AND PLASMA DISPLAY DEVICE THEREWITH earlier filled in the Korean Intellectual Property Office on 10 Nov. 2004 and there duly assigned Serial No. 10-2004-0091526.

### BACKGROUND OF THE INVENTION

1. Field of the Invention

The present invention relates to a Plasma Display Panel (PDP) supporting member and a PDP including the supporting member, and more particularly, a tension member for supporting a PDP and a PDP including the tension member.

2. Description of the Related Art

A PDP is a flat panel display that displays images using a gas discharge phenomenon, and is highlighted as a next generation flat panel display that can substitute for a Cathode Ray Tube (CRT) since it has excellent display characteristics such as display capacity, brightness, contrast, residual image, and viewing angle. The PDP is formed of a glass substrate, and a chassis base supports the PDP.

A structure for supporting a PDP includes a front substrate and a back substrate. The back substrate includes a heat conductive sheet attached to a back surface thereof. The PDP is supported by a chassis base generally formed of a metal such as aluminum. The PDP is attached to a front surface of the chassis base using double-sided tape. The double-sided tape extends in both transverse and longitudinal directions while avoiding portions corresponding to the heat conductive sheet. That is, the double-sided tape and the heat conductive sheet are disposed so as not to overlap each other. Fixing portions are formed on corners of the chassis base. The fixing portions fix the chassis base when attached to another member such as a case.

The PDP is attached to the front surface of the chassis base via the double-sided tape. The heat conductive sheet is arranged between the back surface of the PDP and the front surface of the chassis base and transmits the heat generated by the PDP to the chassis base.

However, the structure for supporting the PDP described above has the following problems.

First, the adhesive force for attaching the PDP to the chassis base using the double-sided tape is not strong enough to firmly attach the PDP to the chassis base. In order to improve the adhesive force using the double-sided tape, the attached area of the double-sided tape must be increased. However, since the double-sided tape cannot overlap the heat conductive sheet, when the attached area of the double-sided tape is increased, the area of the heat conductive sheet must be reduced. Therefore, the heat conductive efficiency is reduced.

In addition, the adhesive force of the double-sided tape can change according to the temperature of the PDP, and especially, when the temperature of the PDP rises due to the surrounding environment and long-time usage, the adhesive force of the double-sided tape is reduced. Thus, the PDP can separate from the chassis base.

In addition, it is difficult to increase the heat conductive efficiency since the area of the heat conductive sheet cannot be increased due to the double-sided tape.

### SUMMARY OF THE INVENTION

The object of the present invention is to provide a PDP supporting member ensuring a supporting structure of a PDP and a chassis base, and a PDP including the supporting member.

According to one aspect of the present invention, a tension member to support a Plasma Display Panel (PDP) is provided, the tension member including: a rim portion extending to surround an edge of the PDP; and curved portions included in the rim portion, the curved portions including substrate insertion holes adapted to receive portions of edges of substrates included in the PDP.

The substrate insertion holes preferably include front substrate insertion holes, and back substrate insertion holes, the front and back substrate insertion holes being arranged at different positions from each other in a width direction of the rim portion.

The curved portions are preferably adapted to isolate the PDP with respect to vibration.

According to another aspect of the present invention, an apparatus is provided including: a front case including a window, and a back case adapted to be attached to the front case to define an inner space; a PDP arranged in the inner space and including a front substrate and a back substrate; a tension member including a rim portion extending to surround an edge of the PDP; and curved portions included in the rim portion, the curved portions including substrate insertion holes adapted to receive portions of edges of substrates included in the PDP; a chassis base adapted to receive the tension member; and a printed circuit board adapted to have a plurality of electronic elements mounted thereon, the printed circuit board arranged on a back surface of the chassis base.

The substrate insertion holes preferably include front substrate insertion holes, and back substrate insertion holes, the front and back substrate insertion holes being arranged at different positions from each other in a width direction of the rim portion.

The curved portions are preferably adapted to isolate the PDP with respect to vibration.

The apparatus preferably further includes a heat conductive sheet arranged between the back substrate of the PDP and the chassis base, the heat conductive sheet covering an entire area of the back substrate.

The tension member is preferably arranged in an inner space provided by a bent portion of an edge of the chassis base, the tension member being attached to the bent portion.

Through holes are preferably arranged on the rim portion of the tension member, and screws inserted into the through holes are adapted to be received by screw recesses arranged in the bent portion of the chassis base to attach the tension member to the chassis base.

According to still another aspect of the present invention, a tension member to support a Plasma Display Panel (PDP) is provided, the tension member including: a rim portion extending to surround an edge of the PDP, the rim portion having a zigzag or serpentine shape; and portions included in the rim portion, the portions included in the rim portion including substrate insertion holes adapted to receive portions of edges of substrates included in the PDP.

The substrate insertion holes preferably include front substrate insertion holes, and back substrate insertion holes, the front and back substrate insertion holes being arranged at different positions from each other in a width direction of the rim portion.

The portions included in the rim portion are preferably adapted to isolate the PDP with respect to vibration.

According to yet another aspect of the present invention, an apparatus is provided including: a front case including a window, and a back case adapted to be attached to the front case to define an inner space; a PDP arranged in the inner space and including a front substrate and a back substrate; a tension member including a rim portion extending to surround an edge of the PDP, the rim portion having a zigzag or serpentine shape; and portions included in the rim portion, the portions included in the rim portion including substrate insertion holes adapted to receive portions of edges of substrates included in the PDP; a chassis base adapted to receive the tension member; and a printed circuit board adapted to have a plurality of electronic elements mounted thereon, the printed circuit board arranged on a back surface of the chassis base.

The substrate insertion holes preferably include front substrate insertion holes, and back substrate insertion holes, the front and back substrate insertion holes being arranged at different positions from each other in a width direction of the rim portion.

The portions included in the rim portion are preferably adapted to isolate the PDP with respect to vibration.

The apparatus preferably further includes a heat conductive sheet arranged between the back substrate of the PDP and the chassis base, the heat conductive sheet covering an entire area of the back substrate.

The tension member is preferably arranged in an inner space provided by a bent portion of an edge of the chassis base, the tension member being attached to the bent portion.

Through holes are preferably arranged on the rim portion of the tension member, and screws inserted into the through holes are adapted to be received by screw recesses arranged in the bent portion of the chassis base to attach the tension member to the chassis base.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a schematic perspective view of a structure for supporting a PDP;

FIG. 2 is a cross-sectional view of an assembled structure for supporting the PDP of FIG. 1;

FIG. 3 is a schematic perspective view of a structure for supporting a PDP according to the present invention;

FIG. 4 is a partial perspective view of a part of the structure shown in FIG. 3;

FIG. 5 is a schematic cross-sectional view of the structure for supporting the PDP of FIG. 4; and

FIG. 6 is a schematic perspective view of a PDP including the PDP supporting structure according to the present invention.

### DETAILED DESCRIPTION OF THE INVENTION

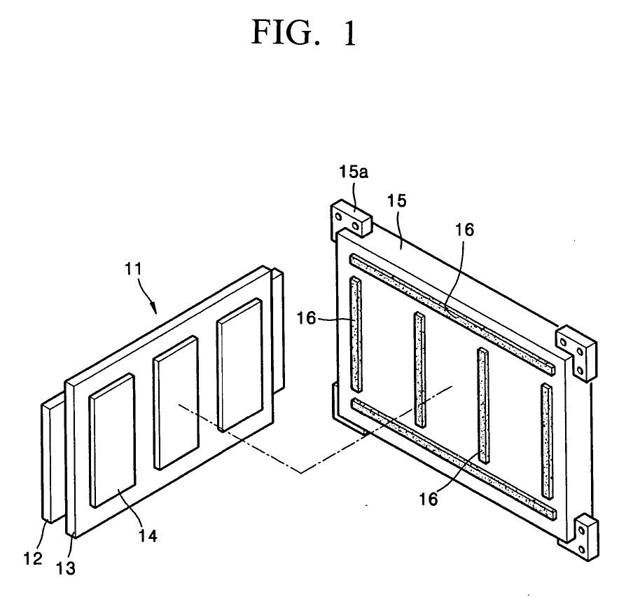

FIG. 1 is a schematic perspective view of a structure for supporting PDP.

Referring to FIG. 1, a PDP 11 includes a front substrate 12, and a back substrate 13. The back substrate 13 includes a heat conductive sheet 14 attached to a back surface thereof. The PDP 11 is supported by a chassis base 15 generally formed of a metal such as aluminum. The PDP 11 is attached to a front surface of the chassis base 15 using double-sided tape 16. As shown in FIG. 1, the double-sided tape 16 extends in both transverse and longitudinal directions while avoiding portions corresponding to the heat conductive sheet 14. That is, the double-sided tape 16 and the heat conductive sheet 14 are disposed so as not to overlap each other. Fixing portions 15a are formed on corners of the chassis base 15. The fixing portions 15a fix the chassis base 15 when attached to another member such as a case (not shown).

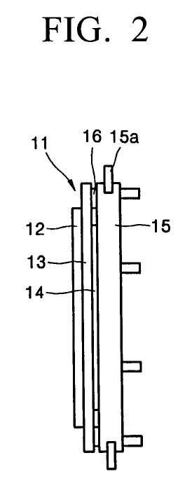

FIG. 2 is a cross-sectional view of an assembled status of the PDP supporting structure of FIG. 1.

Referring to FIG. 2, the PDP 11 is attached to the front surface of the chassis base 15 via the double-sided tape 16. The heat conductive sheet 14 is arranged between the back surface of the PDP 11 and the front surface of the chassis base 15 and transmits the heat generated by the PDP 11 to the chassis base 15.

However, the structure for supporting the PDP described above has the following problems.

First, the adhesive force for attaching the PDP 11 to the chassis base 15 using the double-sided tape 16 is not strong enough to firmly attach the PDP 11 to the chassis base 15. In order to improve the adhesive force using the double-sided tape 16, the attached area of the double-sided tape 16 must be increased. However, since the double-sided tape 16 cannot overlap the heat conductive sheet 14, when the attached area of the double-sided tape 16 is increased, the area of the heat conductive sheet 14 must be reduced. Therefore, the heat conductive efficiency is reduced.

In addition, the adhesive force of the double-sided tape 16 can change according to the temperature of the PDP 11, and especially, when the temperature of the PDP 11 rises due to the surrounding environment and long-time usage, the adhesive force of the double-sided tape 16 is reduced. Thus, the PDP 11 can separate from the chassis base 15.

In addition, it is difficult to increase the heat conductive efficiency since the area of the heat conductive sheet 14 cannot be increased due to the double-sided tape 16.

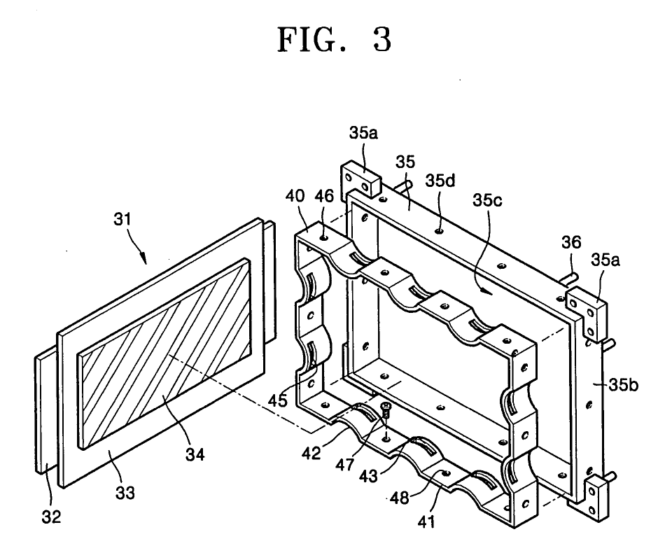

FIG. 3 is a schematic perspective view of a structure for supporting a PDP according to the present invention.

Referring to FIG. 3, a PDP 31 including a front substrate 32 and a back substrate 33 is supported by a tension member 40 for supporting a PDP according to the present invention. The tension member 40 can be mounted in an inner space 35c formed in a chassis base 35 with the PDP 31.

The tension member 40 includes a rim portion 41 extending along an edge of the PDP 31, and curved portions 42 formed on the rim 41. The rim 41 is expanded so as to surround edge of the front substrate 32 and the back substrate 33. The curved portions 42 are formed by curving the rim 41 toward the inside of the tension member 40, and the curved portions 42 include back substrate insertion holes 43 and front substrate insertion holes 45. The substrate insertion holes 43 and 45 formed on the curved portion 42 are formed so that some parts of the substrates 32 and 33 can be inserted therein. Therefore, since the substrates 32 and 33 are inserted into the substrate insertion holes 43 and 45 formed on the curved portions 42 of the tension member 40 at four sides of the panel 31, the panel 31 does not separate from the tension member 40 and can be maintained. In addition, since the tension member 40 is formed of a material having elasticity, weight or vibration of the panel 31 can be maintained/buffered by the movement of the curved portions 42.

Through holes 46 can be formed on flat portions of the rim 41 of the tension member. Screws 47 inserted in the through holes 46 can be arranged in screw recesses 35d formed on the chassis base 35, and the tension member 40 can be fixed onto the chassis base 35 by the screws 47. Otherwise, the tension member 40 can be fixed onto the chassis base 35 by a welding process or double-sided tape.

The panel 31 is continuously supported with respect to the chassis base 35 by the tension member 40. As described above, both side portions of the front glass substrate 32 of the panel 31 are inserted into the front substrate insertion holes 45 formed in the tension member 40, and the back glass substrate 33 is inserted into the back substrate insertion holes 43 formed in the tension member 40. In addition, since the tension member 40 is attached to the chassis base 35 by the screws 47 fastened to the screw recesses 35d formed on bent portion 35b of the chassis base 35, the panel 31, the tension member 40, and the chassis base 35 are assembled and fixed to each other. Fixing portions 35a are formed on four corners of the chassis base 35, and the fixing portions 35a are for fixing the chassis base 35 with respect to a case (not shown). An inner space 35c of the chassis base 35 is formed by the bent portion 35b on the edge of the chassis base 35, and the tension member 40 and the PDP 31 can be mounted in the inner space 35c.

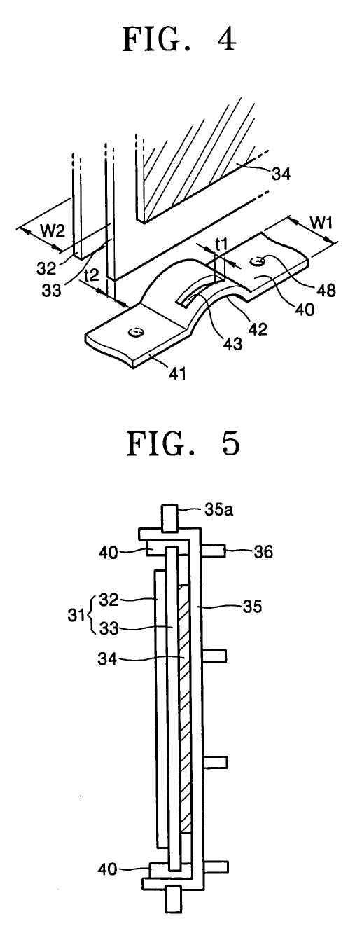

FIG. 4 is a partial perspective view of a portion of the supporting member of FIG. 3.

Referring to FIG. 4, a width of the rim 41 of the tension member 40 is designated W1, and a thickness of the PDP 31 is designated W2. A thickness of the back substrate insertion hole 43 of the curved portion 42 is designated t1, and a thickness of the back substrate 33 of the PDP 31 is designated t2.

The thickness t1 of the back substrate insertion hole 43 is the equal to or greater than the thickness t2 of the back substrate 33, and thus, the back substrate 33 can be inserted into the hole 43. In addition, the thickness W1 of the rim 41 is greater than W2 of the PDP 31. Meanwhile, the back substrate insertion hole 43 is biased toward the back portion in the thickness W1 direction of the rim 41. The front substrate insertion hole 45 (refer to FIG. 3) that is not shown in FIG. 4 is biased toward the front portion. The insertion holes 43 and 45 are biased in different directions from each other in order to correspond to the glass substrates 32 and 33.

FIG. 5 is a schematic cross-sectional view of the structure for supporting the PDP of FIG. 4.

Referring to FIG. 5, the tension member 40 maintains the PDP 35 and is fixed with respect to the chassis base 35. A heat conductive sheet 34 is disposed between the PDP 31 and the chassis base 35, and the heat conductive sheet 34 can be formed on the entire back substrate 33 as shown in FIG. 3.

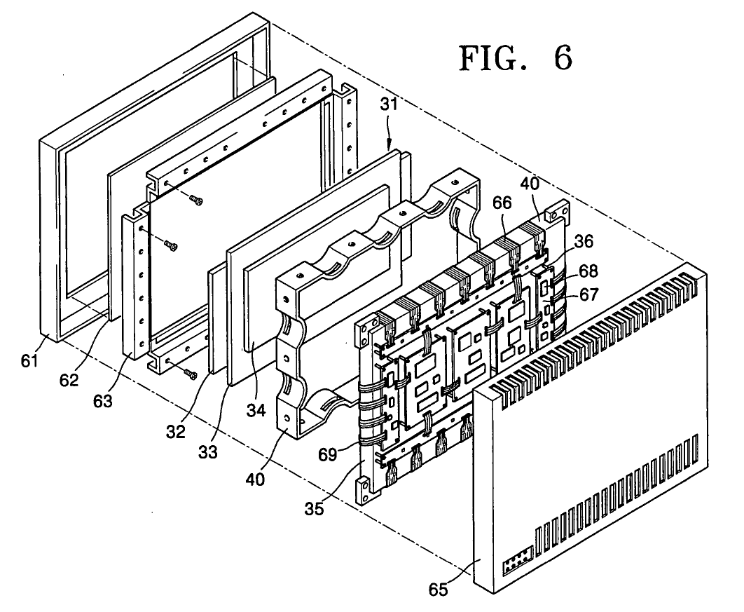

FIG. 6 is a schematic perspective view of a plasma display apparatus including the PDP supporting structure described with reference to FIGS. 3 through 5.

Referring to FIG. 6, the plasma display apparatus includes a front case 61 including a window, a back case 65 attached to the front case 61 to form an inner space, a filter holder 63 installed in the inner space between the front case 61 and the back case 65, a filter 62 maintained by the filter holder 63 and exposed through the window of the front case 61, the PDP 31 located at a back surface of the filter 62, the tension member 40 supporting the PDP 31, and the chassis base 35, on which the tension member 40 is fixed. Printed circuit boards 67 are installed on the back surface of the chassis base 35 by a printed circuit board supporting portion 36, and electronic elements 68 are mounted on the printed circuit boards 67. The fixing portions 35a of the chassis base 35 can be attached to either the front case 61 or the back case 65. Signal transmission cables 66 and 69 electrically connect electrodes formed on the front and back substrates 32 and 33 to the electronic elements 68 on the printed circuit boards 67.

With the tension member for supporting the PDP and the plasma display apparatus including the tension member of the present invention, the PDP can be supported stably, and the heat generated by the PDP can be transmitted effectively to the chassis base. In addition, external shock or vibration applied to the PDP can be absorbed by the tension member.

While the present invention has been particularly shown and described with reference to exemplary embodiments thereof, it will be understood by those of ordinary skill in the art that various modifications in form and detail can be made therein without departing from the spirit and scope of the present invention as defined by the following claims. For example, the rim could have a zigzag shape or a serpentine shape rather than including the curved portions discussed above.

What is claimed is:

1. A tension member to support a Plasma Display Panel (PDP), the tension member comprising:
a rim portion extending to surround an edge of the PDP; and
curved portions included in the rim portion, the curved portions including substrate insertion holes adapted to receive portions of edges of substrates included in the PDP.

2. The tension member of claim 1, wherein the substrate insertion holes include front substrate insertion holes, and back substrate insertion holes, the front and back substrate insertion holes being arranged at different positions from each other in a width direction of the rim portion.

3. The tension member of claim 1, wherein the curved portions are adapted to isolate the PDP with respect to vibration.

4. An apparatus, comprising:
a front case including a window, and a back case adapted to be attached to the front case to define an inner space;
a Plasma Display Panel (PDP) arranged in the inner space and including a front substrate and a back substrate;
a tension member including a rim portion extending to surround an edge of the PDP; and curved portions included in the rim portion, the curved portions including substrate insertion holes adapted to receive portions of edges of substrates included in the PDP;
a chassis base adapted to receive the tension member; and
a printed circuit board adapted to have a plurality of electronic elements mounted thereon, the printed circuit board arranged on a back surface of the chassis base.

5. The apparatus of claim 4, wherein the substrate insertion holes include front substrate insertion holes, and back substrate insertion holes, the front and back substrate insertion holes being arranged at different positions from each other in a width direction of the rim portion.

6. The apparatus of claim 4, wherein the curved portions are adapted to isolate the PDP with respect to vibration.

7. The apparatus of claim 4, further comprising a heat conductive sheet arranged between the back substrate of the PDP and the chassis base, the heat conductive sheet covering an entire area of the back substrate.

8. The apparatus of claim 4, wherein the tension member is arranged in an inner space provided by a bent portion of an edge of the chassis base, the tension member being attached to the bent portion.

9. The apparatus of claim 8, wherein through holes are arranged on the rim portion of the tension member, and wherein screws inserted into the through holes are adapted to be received by screw recesses arranged in the bent portion of the chassis base to attach the tension member to the chassis base.

10. A tension member to support a Plasma Display Panel (PDP), the tension member comprising:
a rim portion extending to surround an edge of the PDP, the rim portion having a zigzag or serpentine shape; and
portions included in the rim portion, the portions included in the rim portion including substrate insertion holes adapted to receive portions of edges of substrates included in the PDP.

11. The tension member of claim 10, wherein the substrate insertion holes include front substrate insertion holes, and back substrate insertion holes, the front and back substrate insertion holes being arranged at different positions from each other in a width direction of the rim portion.

12. The tension member of claim 10, wherein the portions included in the rim portion are adapted to isolate the PDP with respect to vibration.

13. An apparatus, comprising:
a front case including a window, and a back case adapted to be attached to the front case to define an inner space;
a Plasma Display Panel (PDP) arranged in the inner space and including a front substrate and a back substrate;
a tension member including a rim portion extending to surround an edge of the PDP, the rim portion having a zigzag or serpentine shape; and portions included in the rim portion, the portions included in the rim portion including substrate insertion holes adapted to receive portions of edges of substrates included in the PDP;
a chassis base adapted to receive the tension member; and
a printed circuit board adapted to have a plurality of electronic elements mounted thereon, the printed circuit board arranged on a back surface of the chassis base.

14. The apparatus of claim 13, wherein the substrate insertion holes include front substrate insertion holes, and back substrate insertion holes, the front and back substrate insertion holes being arranged at different positions from each other in a width direction of the rim portion.

15. The apparatus of claim 13, wherein the portions included in the rim portion are adapted to isolate the PDP with respect to vibration.

16. The apparatus of claim 13, further comprising a heat conductive sheet arranged between the back substrate of the PDP and the chassis base, the heat conductive sheet covering an entire area of the back substrate.

17. The apparatus of claim 13, wherein the tension member is arranged in an inner space provided by a bent portion of an edge of the chassis base, the tension member being attached to the bent portion.

18. The apparatus of claim 17, wherein through holes are arranged on the rim portion of the tension member, and wherein screws inserted into the through holes are adapted to be received by screw recesses arranged in the bent portion of the chassis base to attach the tension member to the chassis base.
